(19) United States
(12) Patent Application Publication
(10) Pub. No.: US 2024/0352618 A1
(43) Pub. Date: Oct. 24, 2024

(54) REFLECTOR FOR PROCESS CHAMBER

(71) Applicant: Applied Materials, Inc., Santa Clara, CA (US)

(72) Inventors: Vishwas Kumar PANDEY, Madhya Pradesh (IN); Hemantha Kumar RAJU, Bangalore (IN); Ala MORADIAN, Sunnyvale, CA (US); Anilkumar BODEPUDI, Bangalore (IN)

(21) Appl. No.: 18/418,531

(22) Filed: Jan. 22, 2024

(30) Foreign Application Priority Data
Apr. 20, 2023 (IN) 202341028740

(51) Int. Cl. C30B 25/10; B08B 7/00

(52) U.S. Cl. CPC C30B 25/10; B08B 7/0071

(57) ABSTRACT

A reflector for use in a semiconductor process chamber is provided including: a body; and a bottom plate connected to a lower portion of the body, the bottom plate having a bottom surface, a top surface, and one or more side surfaces connecting the bottom surface with the top surface. A cross section of the bottom plate that extends to opposing locations on the one or more side surfaces includes a center, the cross section is divided into two or more sectors that extend from the center of the cross section, and the cross section includes a cooling channel comprising an inlet and one or more outlets.

### RELATED APPLICATIONS

This application claims benefit of and priority to Indian Patent Application No. 202341028740, filed Apr. 20, 2023, the entire contents of which are incorporated herein by reference.

### BACKGROUND

Embodiments of the present disclosure generally relate to improved reflectors for use in process chambers, such as semiconductor process chambers.

### DESCRIPTION OF THE RELATED ART

Cleaning the interior of process chambers, such as semiconductor process chambers, can improve the product quality of substrates processed in the process chambers. The interior of the process chambers are often heated during these cleaning procedures because heat can assist in removal of deposits on the surfaces of components in the interior of the process chambers. Generally, higher temperatures result in achieving a higher level of cleanliness and/or enabling a faster cleaning procedure to be completed.

Although higher temperatures can improve the cleaning of process chambers, high temperatures can also damage components in the chamber exposed to the high temperatures of the cleaning process. As dimensions on semiconductor components continue to increase, the demands for cleanliness continue to grow. Accordingly, there is an ongoing need for methods and related equipment that enable improved cleaning procedures to be performed.

### SUMMARY

In one embodiment, a reflector for use in a semiconductor process chamber is provided comprising: a body; and a bottom plate connected to a lower portion of the body, the bottom plate having a bottom surface, a top surface, and one or more side surfaces connecting the bottom surface with the top surface, wherein a cross section of the bottom plate that extends to opposing locations on the one or more side surfaces includes a center, the cross section is divided into two or more sectors that extend from the center of the cross section, and the cross section includes a cooling channel comprising an inlet and one or more outlets.

In another embodiment, a process chamber is provided comprising: a chamber body disposed around a process volume; a substrate support in the process volume; a reflector positioned over the substrate support, the reflector comprising: a bottom plate having a bottom surface facing the substrate support, a top surface, and one or more side surfaces connecting the bottom surface with the top surface, wherein a cross section of the bottom plate that extends to opposing locations on the one or more side surfaces includes a center, the cross section is divided into two or more sectors that extend from the center of the cross section, and the cross section includes a cooling channel comprising an inlet and one or more outlets.

In another embodiment, a process chamber is provided comprising: a chamber body disposed around a process volume; a substrate support in the process volume; a reflector positioned over the substrate support, the reflector comprising: a bottom plate having a bottom surface facing the substrate support, a top surface, and one or more side surfaces connecting the bottom surface with the top surface, wherein a cross section of the bottom plate that extends to opposing locations on the one or more side surfaces includes a center, the cross section is divided into four or more sectors that extend from the center of the cross section, and the cross section includes a cooling channel comprising: an inlet and one or more outlets; and a plurality of sections, each section located entirely in a sector of the four or more sectors of the cross section of the bottom plate, wherein each section each section includes three or more turns of 180 degrees in a radially outward direction.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a cross-sectional view of a processing system, according to one embodiment.

FIG. 2 is a top view of a cross section of the interior of the bottom plate of the reflector of FIG. 1, according to one embodiment.

FIG. 3 is a top view of a cross section of an interior of a bottom plate of an alternative reflector, according to another embodiment.

FIG. 4 is a top view of a cross section of an interior of a bottom plate of an alternative reflector, according to another embodiment.

FIG. 5 is a top view of a cross section of an interior of a bottom plate of an alternative reflector, according to another embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to improved reflectors for use in process chambers, such as semiconductor process chambers. The reflectors described in this disclosure each include one or more cooling channels that allow for a flow of coolant to be provided through the one or more channels during cleaning procedures and other procedures. The flow of coolant through the one or more cooling channels enables the reflector to have a more uniform temperature across different locations of the reflector as well as a lower maximum temperature during high-temperature processes (e.g., high-temperature cleaning processes) when compared to the temperatures of an otherwise similar reflector without the one or more cooling channels during a same high-temperature process. Because the one or more cooling channels improve the temperature uniformity of the reflector and lower the maximum temperature of the reflector during a high-temperature process, processes can be run at higher internal temperatures without a portion of the reflector increasing to a temperature (e.g., greater than 700° C. or greater than 800° C.) that would result in damage of the reflector. These higher internal temperatures for the cleaning processes can result in a cleaner process chamber and/or a process chamber that can be cleaned more quickly when compared to similar cleaning processes performed on chambers having otherwise similar reflectors without the one or more cooling channels described in this disclosure.

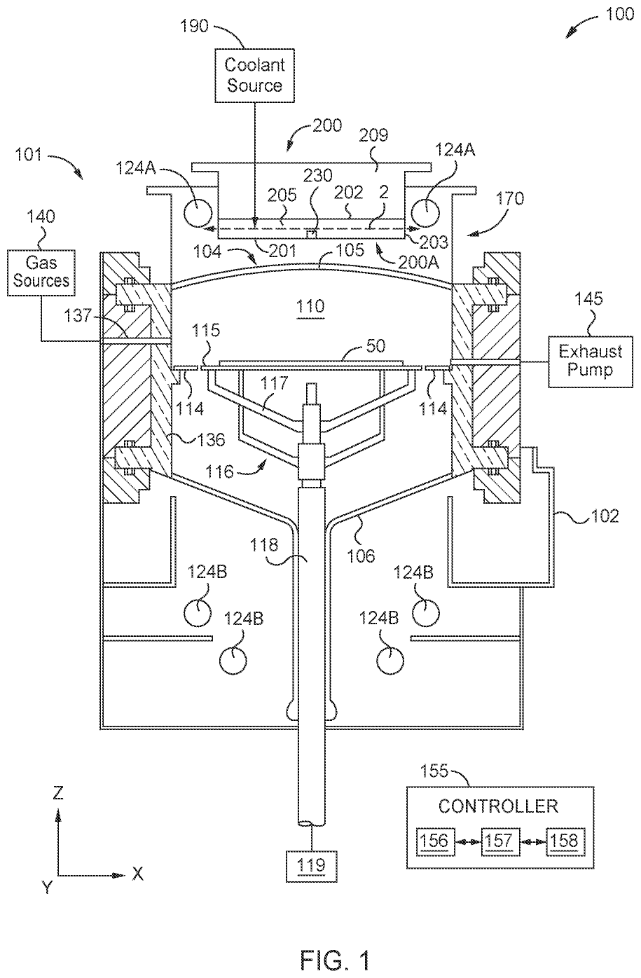

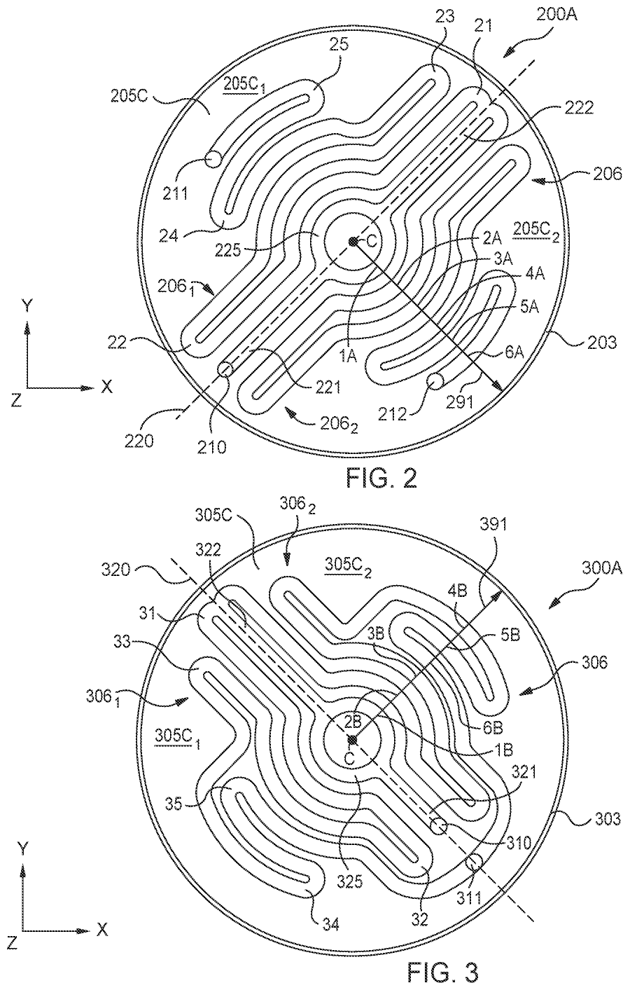

FIG. 1 is a cross-sectional view of a processing system 100, according to one embodiment. The processing system 100 includes a process chamber 101, one or more gas sources 140, an exhaust pump 145, a coolant source 190, and a controller 155. The processing system 100 can be configured to perform epitaxial deposition processes in the process chamber 101 as well as one or more cleaning processes to clean the interior of the process chamber 101. The process chamber 101 includes an inner reflector 200 that includes a bottom reflector plate 200A. The bottom reflector plates (e.g., bottom reflector plate 200A) described in this disclosure include cooling channels that enable high-temperature processes (e.g., cleaning) to be performed in the interior of the process chamber 101 at higher temperatures than would otherwise be possible without damaging components in the process chamber. Enabling these cleaning processes to be executed at higher temperatures can improve the cleaning of the processing chamber and/or enable the cleaning procedure to be completed more quickly. Additional details on the cooling channels for different embodiments of bottom reflector plates are described in reference to FIGS. 2-5 below.

The process chamber 101 includes a housing structure 102 made of a process resistant material, such as aluminum or stainless steel, for example 316L stainless steel. The housing structure 102 encloses various functioning elements of the processing chamber 101, such as a quartz chamber 104, which includes an upper quartz chamber 105 and a lower quartz chamber 106. The quartz chamber 104 encloses an interior volume 110 (also referred to as process volume). One or more liners 136, 137 can insulate the quartz chamber 104 from the housing structure 102.

The processing chamber 101 includes a substrate support assembly 116. The substrate support assembly 116 can include supports 117 and a shaft 118. A susceptor 115 can be positioned on the supports 117. The substrate support assembly 116 can further include an actuator 119 to rotate the shaft 118 and the susceptor 115. A substrate 50 can be positioned on the susceptor 115 during processing, such as during an epitaxial deposition. Generally, a substrate is not positioned on the susceptor 115 during the cleaning processes described in this disclosure.

Gases can be provided to the interior volume 110 from the gas sources 140 during depositions and cleaning processes. These gases can be exhausted from the interior volume 110 by the exhaust pump 145. The process chamber can further include a preheat ring 114 that can be positioned around the susceptor 115.

The process chamber 101 can further include upper lamp modules 124A and lower lamp modules 124B for heating of the substrate 50 and/or the interior volume 110. In one embodiment, the upper lamp modules 124A and the lower lamp modules 124B are infrared (IR) lamps.

The process chamber 101 further includes an outer reflector 170 and the inner reflector 200 introduced above. The outer reflector 170 can be positioned around the inner reflector 200. In some embodiments one or more upper lamp modules 124A can be positioned inside the outer reflector 170.

The inner reflector 200 includes a body 209 and the bottom plate 200A connected to a lower portion of the body 209. The bottom plate 200A includes a bottom surface 201, a top surface 202, and one or more side surfaces 203 connecting the bottom surface 201 with the top surface 202. The bottom surface 201, the top surface 202, and the one or more side surfaces 203 can enclose an interior 205 of the bottom plate 200A. Coolant (e.g., cooling water) can be provided from the coolant source 190 to a cooling channel 206 (FIG. 2) in the interior 205 of the inner reflector 200. In some embodiments, the bottom surface 201 is formed of gold. In some embodiments, the bottom surface 201 is a gold coating formed over a copper or aluminum base.

The process chamber 101 further includes a temperature sensor 230. In some embodiments, the temperature sensor 230 can be a thermocouple. The temperature sensor 230 can be used to monitor a temperature of the bottom surface 201 of the bottom plate 200A, for example during high-temperature cleaning processes. The controller 155 can use the measurements from the temperature sensor 230 to control the temperature of the bottom plate 200A. For example, in some embodiments, the controller 155 can adjust the positions of valves or the speed of one or more pumps to adjust a flowrate of coolant through the bottom plate 200A to control the temperature of the bottom plate 200A during a high-temperature process, such as a cleaning process.

The processing system 100 also includes the controller 155 for controlling processes performed by the processing system 100. The controller 155 can be any type of controller used in an industrial setting, such as a programmable logic controller (PLC). The controller 155 includes a processor 157, a memory 156, and input/output (I/O) circuits 158. The controller 155 can further include one or more of the following components (not shown), such as one or more power supplies, clocks, communication components (e.g., network interface card), and user interfaces typically found in controllers for semiconductor equipment.

The memory 156 can include non-transitory memory. The non-transitory memory can be used to store the programs and settings described below. The memory 156 can include one or more readily available types of memory, such as read only memory (ROM) (e.g., electrically erasable programmable read-only memory (EEPROM), flash memory, floppy disk, hard disk, or random access memory (RAM) (e.g., non-volatile random access memory (NVRAM).

The processor 157 is configured to execute various programs stored in the memory 156, such as epitaxial deposition processes and high-temperature cleaning processes. During execution of these programs, the controller 155 can communicate to I/O devices through the I/O circuits 158. For example, during execution of these programs and communication through the I/O circuits 158, the controller 155 can control outputs, such as the power provided to the lamp modules 124A, 124B for heating the components in the interior volume 110 and position of valves and/or speed of pumps for controlling the flowrate of coolant through the reflector 200. The memory 156 can further include various operational settings used to control the processing system 100. For example, the settings can include temperature setpoints for the bottom surface 201 of the bottom plate 200A of the reflector 200 during different processes. Continuing the example, the controller 155 can adjust the position of one or more valves and/or the speed of one or more pumps to adjust the flowrate of coolant through the bottom plate 200A based on measurements from the temperature sensor 230 to ensure that the temperature of the bottom surface 201 of the bottom plate 200A is maintained within an acceptable threshold of the temperature setpoint during high-temperature cleaning processes.

FIG. 2 is a top view of a cross section 205C of the interior 205 of the bottom plate 200A of the reflector 200 of FIG. 1, according to one embodiment. The view of the cross section 205C is taken along section line 2 of FIG. 1.

The bottom plate 200A includes a cooling channel 206 that extends through the interior 205 of the bottom plate 200A. The cross section 205C of the interior 205 of the bottom plate 200A includes a center C. The cross section 205C includes a first sector 205C₁ and a second sector 205C₂. The first sector 205C₁ is on a first side of an imaginary dividing line 220 that bisects the cross section 205C through the center C. The second sector 205C₂ is on a second side of the dividing line 220. The cooling channel 206 includes a first section 206₁ located in the first sector 205C₁. The cooling channel 206 includes a second section 206₂ located in the second sector 205C₂.

The cooling channel 206 includes an inlet 210 configured to allow coolant to enter the cooling channel 206. The inlet 210 is located partially in the first sector 205C₁ and partially in the second sector 205C₂. The cooling channel 206 further includes a first outlet 211 and second outlet 212 configured to allow coolant to leave the cooling channel 206. The first outlet 211 is located in the first sector 205C₁. The second outlet 212 is located in the second sector 205C₂.

Although not required, the first section 206₁ can be a mirror image of the second section 206₂, for example as shown in FIG. 2. The cooling channel 206 includes a central loop 225 that surrounds the center C of the cross section 205C. In some embodiments, the central loop 225 can be a first portion of the cooling channel 206 downstream from the inlet 210 to extend at least 30 degrees, such as at least 90 degrees, such as at least 180 degrees, such as 360 degrees around the center C of the cross section 205C. The other central loops described in this disclosure, such as central loops 325, 425, and 525 (see FIGS. 3, 4, and 5) can also be the first portions downstream from the respective inlets to extend for at least 30 degrees, such as at least 90 degrees, such as at least 180 degrees, such as for 360 degrees around the center C of the corresponding cross section

The central loop 225 can further include a first segment 221 that connects the inlet 210 to the central loop 225. In some embodiments, the first segment 221 can be a straight segment with no turns from the inlet 210 to the central loop 225. Having the central loop 225 directly connected to the inlet 210 by a straight path can allow coolant having some of the lowest temperatures in the cooling channel 206 to flow around the portion of the cooling channel 206 (i.e., central loop 225) that is closest to the center C during a high-temperature processing being performed in the process chamber 101, such as a high-temperature cleaning process. This can be useful, for example, when the center of the bottom surface 201 of the bottom plate 200A of the reflector is heated to higher temperatures than other portions of the bottom surface 201 when cooling is not used during otherwise similar high-temperature processes.

The cooling channel 206 extends downstream from the central loop 225 to a second segment 222. From the second segment 222, the cooling channel 206 extends along a downstream path in each section 206₁, 206₂ that includes a series of turns extending in a radially outward direction from the center C with each section 206₁, 206₂ ending at one of the corresponding outlets 211, 212. For example, the first section 206₁ includes five turns 21-25 with each turn 21-25 providing a path to move the coolant downstream in a radially outward direction. Although not labeled in FIG. 2, the second section 206₂ includes the same five turns 21-25. In some embodiments, each section includes at least two turns, such as at least three turns, or six or more turns in a radially outward direction.

Each of the five turns 21-25 are configured to change the direction of the coolant and the cooling channel by 180 degrees relative to the direction of the cooling channel 206 before the corresponding turn. Although the turns 21-25 change direction of the coolant channel by 180 degrees, other turns can change direction of the cooling channel by lesser amounts, such as by 90 degrees, 45 degrees, or 30 degrees. Used herein, a turn corresponds to a section of a cooling channel that changes the prior direction of the downstream path by at least 30 degrees using a radius of curvature that is less than 50% of the radius between the center C and the location of the turn, such as a radius of curvature that is less than 25% of the radius between the center C and the location of the turn, such as a radius of curvature that is less than 10% of the radius between the center C and the location of the turn.

Although all of the turns 21-25 extend from upstream to downstream in a radially outward direction, in some embodiments some of the turns extend from upstream to downstream in a radially inward direction. In some of these embodiments, a number of the turns in a radially outward direction from upstream to downstream is greater than a number of the turns in a radially inward direction from upstream to downstream, which can assist in causing more of the coolant having lower temperatures to be exposed to radially inward locations and more of the coolant having higher temperatures to be exposed to more radially outward locations.

The cooling channel 206 in each section 206₁, 206₂ extends from the turns 21-25 towards a corresponding arc 2A-6A with each arc 2A-6A being located radially outward from the center C relative to another arc. In some embodiments, the arcs 2A-6A can be concentric arcs, such as arcs all centered around the center C of the cross section 205C. Furthermore, each arc 2A-6A can be concentric with an arc 1A that forms a portion of the central loop 225. Arc 1A is the most radially inward arc of the arcs 1A-6A. In this disclosure, although portions of the cooling channels are described as having the shapes or arcs (e.g., arcs 2A-6A), there is no requirement for these portions to have an arc shape, and many if not all of the benefits of the cooling channels described herein can be obtained using portions of cooling channels with other shapes.

Each arc 1A-6A (also referred to as one or more or three or more portions) can also extend through a first angular location 291 in the sector relative to the center C of the cross section 205C with each arc 1A-6A extending at a different radial distance from the center C. The first angular location 291 is shown in the second sector 205C₂, but a corresponding angle is also located in the first sector 205C₁. In some embodiments, each arc 2A-6A can extend in an angular direction around the center C of the cross section 205C for at least 15 degrees, such as for at least 30 degrees, such as for at least 45 degrees, such as for at least 90 degrees, such as for at least 120 degrees, such as for at least 180 degrees (e.g., if each arc started and ended on the dividing line 220).

For each section 206₁, 206₂, each turn 22-25 is connected to an arc 2A-6A that is located at a further radial distance from the center C compared to the arc 2A-6A connected to the previous turn 21-24. For example, the second turn 22 is connected to the arc 3A, which is located at a further radial distance relative to the center C compared to the arc 2A, which is connected to the first turn 21.

Each of the arcs 2A-6A is also downstream relative to the corresponding next closest radially inward arc 1A-5A. For example, arc 2A is located downstream of the next radially inward arc 1A, arc 3A is located downstream of the next radially inward arc 2A, arc 4A is located downstream of the next radially inward arc 3A, arc 5A is located downstream of the next radially inward arc 4A, and arc 6A is located downstream of the next radially inward arc 5A. This configuration of progressively radially outwards arcs as the coolant flows downstream enables the coolant to remove greater amounts of heat per unit area of the cooling channel 206 from locations closer to the center C because the coolant with the lower temperatures flows through the radially inwards locations first, and then the coolant gradually heats up through each arc 1A-6A and turn as the coolant flows through each portion of the corresponding section 206₁, 206₂ in a radially outward manner. Although all arcs 2A-6A are located downstream of a next radially inward arc 1A-5A, in some embodiments less than all, but more than half of the arcs (also referred to as portions) are located downstream relative to a next closest radially inward arc.

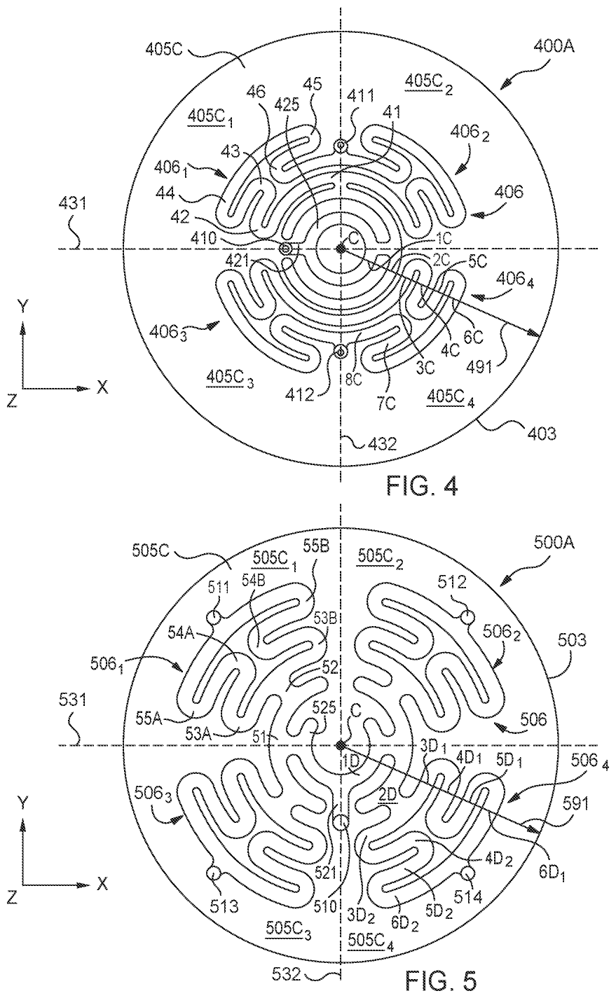

Furthermore, although FIG. 2 is shown being arranged in two sectors, in other embodiments, three or more sectors can be used. For example, FIGS. 4 and 5 show embodiments in which the cooling channels are arranged in four sectors, but more than four sectors can also be used. Similarly, although not shown an embodiment including a single sector could be used, such as cooling channel that spirals outwardly from an inner location around the center C as the cooling channel extends downstream to make numerous 360 degree loops around the center C.

Although not required, in some embodiments, each section, such as sections 206₁, 206₂, can be located entirely within a corresponding sector, such as sectors 205C₁, 205C₂, without entering the other sector, so that each section has greater control of the temperature of the corresponding sector Furthermore, in some embodiments, each section, such as sections 206₁, 206₂, can have an independent inlet and outlet, so that different flowrates can be used through each section to make the temperature control of each section independent from the temperature control of the other section. In some embodiments, the outlets can be located at a greatest radial distance from the center C for the entire cooling channel. This enables the coolant with the highest temperature to be located at the greatest radial distance from the center C. Where applicable, all of the variations described in reference to the bottom plate 200A can also apply to the bottom plates 300A-500A described below in reference to FIGS. 3-5.

FIG. 3 is a top view of a cross section 305C of an interior of a bottom plate 300A of an alternative reflector, according to another embodiment. The bottom plate 300A can be the same as the bottom plate 200A described above except that the bottom plate 300A includes a different cooling channel configuration.

The bottom plate 300A includes a cooling channel 306 that extends through the interior of the bottom plate 300A. The cross section 305C of the interior of the bottom plate 300A includes the center C. The cross section 305C includes a first sector 305C₁ and a second sector 305C₂ each extending from the center C. The first sector 305C₁ is on a first side of an imaginary dividing line 320 that bisects the cross section 305C through the center C. The second sector 305C₂ is on a second side of the dividing line 320. The cooling channel 306 includes a first section 306₁ located in the first sector 305C₁. The cooling channel 306 includes a second section 306₂ located in the second sector 305C₂.

The cooling channel 306 includes an inlet 310 configured to allow coolant to enter the cooling channel 306. The cooling channel 306 further includes an outlet 311 configured to allow coolant to leave the cooling channel 306. The inlet 310 and the outlet 311 are each located partially in the first sector 305C₁ and partially in the second sector 305C₂.

Although not required, the first section 306₁ can be a mirror image of the second section 306₂, for example as shown in FIG. 3. The cooling channel 306 includes a central loop 325 that surrounds the center C of the cross section 305C. The cooling channel 306 can further include a first segment 321 that connects the inlet 310 to the central loop 325. In some embodiments, the first segment 321 can be a straight segment with no turns from the inlet 310 to the central loop 325. Having the central loop 325 directly connected to the inlet 310 by a straight path can allow coolant having some of the lowest temperatures in the cooling channel 306 to flow around the portion of the cooling channel 306 (i.e., central loop 325) that is closest to the center C during a high-temperature process being performed in the process chamber, such as a high-temperature cleaning process.

The cooling channel 306 extends from the central loop 325 to a second segment 322. From the second segment 322, the cooling channel 306 extends along a path in each section 306₁, 306₂ that includes a series of turns extending in a radially outward or radially inward direction from the center C with each section 306₁, 306₂ ending at the outlet 311. For example, the first section 306₁ includes five turns 31-35 with each turn 31-35 providing a path to move the coolant in a radially outward or radially inward direction. For example, the first, second, and third turns 31-33 each move the coolant and extend the cooling channel 306 in a radially outward direction while the fourth and fifth turns 34, 35 each move the coolant and extend the cooling channel 306 in a radially inward direction. With three turns 31-33 in a radial outward direction and two turns 34, 35 in a radially inward direction, more than half of the turns extend in a radial outward direction, which can assist in providing more of the cooling towards central regions than regions near the outer edge.

Having one or more turns that extend the cooling channel 306 in a radially outward direction and one or more turns that extend the cooling channel 306 in a radially inward direction can be used to have the temperature of the coolant (1) increase in a radial direction after each of the radial outward turns towards greater radial distances from the center C and then (2) increase in a radial inward direction after each of the radial inward turns towards lesser radial distances relative to the center C. Having the temperature of the coolant increase in a radial outward direction and then increase in a radial inward direction can be used to reduce the difference between the rates of heat transfer per unit area around the center C (e.g., around central loop 325) compared to portions of the cooling channel 306 near the edge 303 of the bottom plate 300A, such as arc 4B described below. This can be useful for removing more heat near the edge 303 of the bottom plate 300A compared to cooling channels that mainly or only turn in a radially outward direction on each successive turn, such as the turns 21-25 of the cooling channel 206 in FIG. 2.

Although not labeled in FIG. 3, the second section 306₂ includes the same five turns 31-35. Each of the five turns 31-35 are configured to change the direction of the coolant and the cooling channel 306 by 180 degrees relative to the direction of the cooling channel 306 before the corresponding turn. The sections 306₁, 306₂, include two turns of about 90 degrees between the third turn 33 and the fourth turn 34, but these two turns result in the sections extending in substantially the same direction after these two turns as directly after the third turn 33.

Each turn 31-35 extends towards an arc 2B-6B. The first turn 31 extends in a radially outward direction towards the arc 2B. The second turn 32 extends in a radially outward direction towards the arc 3B. The third turn 33 extends in a radially outward direction towards the arc 4B. The fourth turn 34 extends in a radially inward direction towards the arc 5B. The fifth turn 35 extends in a radially inward direction towards the arc 6B.

In some embodiments, the arcs 2B-6B can be concentric arcs, such as arcs all centered around the center C of the cross section 305C. Furthermore, each arc 2B-6B can be concentric with an arc 1B that forms a portion of the central loop 325. In some embodiments, each arc 2B-6B can extend in an angular direction around the center C of the cross section 305C for at least 15 degrees, such as for at least 30 degrees, such as for at least 45 degrees, such as for at least 90 degrees, such as for at least 120 degrees, such as for at least 180 degrees (e.g., if each arc started and ended on the dividing line 320). Each arc 1B-6B can also extend through a same first angular location 391 in the sector relative to the center C of the cross section 305C with each arc 1B-6B extending at a different radial distance from the center C. The first angular location 391 is shown in the second sector 305C₂, but a corresponding angle is also located in the first sector 305C₁.

FIG. 4 is a top view of a cross section 405C of an interior of a bottom plate 400A of an alternative reflector, according to another embodiment. The bottom plate 400A can be the same as the bottom plate 200A described above (see FIG. 2) except that the bottom plate 400A includes a different cooling channel configuration.

The bottom plate 400A includes a cooling channel 406 that extends through the interior of the bottom plate 400A. The cross section 405C of the interior of the bottom plate 400A includes a center C. The cross section 405C includes a first sector 405C₁, a second sector 405C₂, a third sector 405C₃, and a fourth sector 405C₄. Each sector extends from the center C of the cross section 405C. Imaginary perpendicular dividing lines 431, 432 are shown extending through the center C of the cross section 405C in FIG. 4 to show how the different sectors 405C₁-405C₄ are arranged.

The dividing lines 431, 432 divide the cross section 405C into four equally sized sectors. The first sector 405C₁ is above the first dividing line 431 and to the left of the second dividing line 432. The second sector 405C₂ is above the first dividing line 431 and to the right of the second dividing line 432. The third sector 405C₃ is below the first dividing line 431 and to the left of the second dividing line 432. The fourth sector 405C₄ is below the first dividing line 431 and to the right of the second dividing line 432.

The cooling channel 406 includes a first section 406₁ located in the first sector 405C₁. The cooling channel 406 includes a second section 406₂ located in the second sector 405C₂. The cooling channel 406 includes a third section 406₃ located in the third sector 405C₃. The cooling channel 406 includes a fourth section 406₄ located in the fourth sector 405C₄.

The four sections 406₁-406₄ have highly similar shapes. The first section 406₁ can be a mirror image of the third section 406₃. The second section 406₂ can be a mirror image of the fourth section 406₄. In some embodiments, the outer regions of each section 406₁-406₄ can be identical in each section 406₁-406₄, such as for radial distances from the center C greater than a third portion 3C of each section 406₁-406₄ as described below.

The cooling channel 406 includes an inlet 410 configured to allow coolant to enter the cooling channel 406. The inlet 410 is located partially in the first sector 405C₁ and partially in the third sector 405C₃. The cooling channel 406 further includes a first outlet 411 and second outlet 412 configured to allow coolant to leave the cooling channel 406. The first outlet 411 is located partially in the first sector 405C₁ and partially in the second sector 405C₂. The second outlet 412 is located partially in the third sector 405C₃ and partially in the fourth sector 405C₄.

The cooling channel 406 includes a central loop 425 that surrounds the center C of the cross section 405C. The cooling channel 406 can further include a first segment 421 that connects the inlet 410 to the central loop 425. In some embodiments, the first segment 421 can be a straight segment with no turns from the inlet 410 to the central loop 425. Having the central loop 425 directly connected to the inlet 410 by a straight path can allow coolant having some of the lowest temperatures in the cooling channel 406 to flow around the portion of the cooling channel 406 (i.e., central loop 425) that is closest to the center C during a high-temperature process being performed in the process chamber, such as a high-temperature cleaning process.

Each section 406₁-406₄ includes four radially outward turns 41-44 and two radially inward turns 45, 46. Additionally each section 406₁-406₄ includes a central portion 1C that forms part of the central loop 425. The central portions 1C of each section 406₁-406₄ can combine to form a complete loop (i.e., 360 degrees around the center C). Each section 406₁-406₄ includes a second portion 2C having an arc shape and extending at a radial distance from the center C that is greater than the radial distance of the central portion 1C from the center C.

With reference to the first section 406₁ for the turns 41-46 and the fourth section 406₄, for the portions 1C-6C, in each section 406₁-406₄ (1) a first turn 41 connects the second portion 2C to a more radially outward third portion 3C, (2) a second turn 42 connects the third portion 3C to a more radially outward fourth portion 4C, (3) a third turn 43 connects the fourth portion 4C to a more radially outward fifth portion 5C, (4) a fourth turn 44 connects the fifth portion 5C to a more radially outward sixth portion 6C, (5) a fifth turn 45 connects the sixth portion 6C to a more radially inward fourth portion 7C, and (6) a sixth turn 46 connects the seventh portion 7C to a more radially inward eighth portion 8C. The eighth portion 8C of each section 406₁-406₄ is connected to the one of the outlets 411, 412.

Having the coolant move in a radial outward direction from the first central portion 1C to the sixth portion 6C can enable more heat transfer per unit area by the coolant at radial inward locations relative to radial outward locations. Additionally having the last two portions 7C, 8C located radially inward relative to the sixth section 6C can assist in preventing locations on the bottom plate 400A near the outer edge 403 from becoming too hot as the coolant in the sixth section 6C (i.e., the outermost section closest to the edge 403) has a lower temperature than the coolant in the seventh portion 7C and eighth portion 8C due to the temperature of the coolant increasing in each section from the inlet 410 to one of the outlets 411, 412.

In some embodiments, the portions 1C-8C (also referred to as arcs 1C-8C) can be concentric arcs, such as arcs all centered around the center C of the cross section 405C. Each arc 1C-8C can extend in an angular direction around the center C of the cross section 405C for at least 15 degrees, such as for at least 30 degrees, such as for at least 45 degrees, such as for at least 90 degrees. For embodiments in which each arc 1C-8C extends for at least 90 degrees, each arc 1C-8C can be located at a different radial distance from the center C as opposed from some of the arcs being located at a same radial distance from the center C (e.g., arcs 4C and 8C). In some embodiments two or more or three or more of the arcs 1C-8C can each extend past a same angular location in the sector, such as a first angular location 491, but at a different radial distance relative to the center C. For example, each of the arcs 1C-6C extend past the first angular location 491 in the sector but at a different radial distance relative to the center C. At the first angular location 491, each arc 20-6C is downstream relative to a next closest radially inward portion of the arcs 10-5C. At some angular locations in each section 406₁-406₄, more than half of the three or more of the arcs 1C-8C are downstream relative to a next closest radially inward arc of the three or more arcs 1C-8C. The first angular location 491 is shown in the fourth sector 405C₄, but a corresponding angle is also located in each of the other sectors 405C₁₋₃.

FIG. 5 is a top view of a cross section 505C of an interior of a bottom plate 500A of an alternative reflector, according to another embodiment. The bottom plate 500A can be the same as the bottom plate 400A described above (see FIG. 4) except that the bottom plate 500A includes a different cooling channel configuration.

The bottom plate 500A includes a cooling channel 506 that extends through the interior of the bottom plate 500A. The cross section 505C of the interior of the bottom plate 500A includes a center C. The cross section 505C includes a first sector 505C₁, a second sector 505C₂, a third sector 505C₃, and a fourth sector 505C₄. Each sector 505C₁-505C₄ can extend from the center C of the cross section 505C. Imaginary perpendicular dividing lines 531, 532 are shown extending through the center C of the cross section 505C in FIG. 5 to show how the different sectors 505C₁-505C₄ are arranged.

The dividing lines 531, 532 divide the cross section 505C into four equally sized sectors 505C₁-505C₄. The first sector 505C₁ is above the first dividing line 531 and to the left of the second dividing line 532. The second sector 505C₂ is above the first dividing line 531 and to the right of the second dividing line 532. The third sector 505C₃ is below the first dividing line 531 and to the left of the second dividing line 532. The fourth sector 505C₄ is below the first dividing line 531 and to the right of the second dividing line 532.

The cooling channel 506 includes a first section 506₁ located in the first sector 505C₁. The cooling channel 506 includes a second section 506₂ located in the second sector 505C₂. The cooling channel 506 includes a third section 506₃ located in the third sector 505C₃. The cooling channel 506 includes a fourth section 506₄ located in the fourth sector 505C₄.

The four sections 506₁-506₄ have highly similar shapes. The first section 506₁ can be a mirror image of the second section 506₂. The third section 506₃ can be a mirror image of the fourth section 506₄. In some embodiments, the outer regions of each section 506₁-506₄ can be identical in each section 506₁-506₄, such as for radial distances from the center C greater than a third portion 3D described below for each section 506₁-506₄.

The cooling channel 506 includes an inlet 510 configured to allow coolant to enter the cooling channel 506. The inlet 510 is located partially in the third sector 505C₃ and partially in the fourth sector 505C₄. The cooling channel 506 further includes an outlet 511-514 in each sector 505C₁-505C₄ that is configured to allow coolant to leave the cooling channel 506. The first outlet 511 is located in the first sector 505C₁. The second outlet 512 is located in the second sector 505C₂. The third outlet 513 is located in the third sector 505C₃. The fourth outlet 514 is located in the fourth sector 505C₄. The outlet 511-514 for each section 506₁-506₄ is located at an outermost radial position of the corresponding section 506₁-506₄.

The cooling channel 506 includes a central loop 525 that partially surrounds the center C of the cross section 505C for greater than 180 degrees. The cooling channel 506 can further include a first segment 521 that connects the inlet 510 to the central loop 525. In some embodiments, the first segment 521 can be a straight segment with no turns from the inlet 510 to the central loop 525. Having the central loop 525 directly connected to the inlet 510 by a straight path can allow coolant having some of the lowest temperatures in the cooling channel 506 to flow around the portion of the cooling channel 506 (i.e., central loop 525) that is closest to the center C during a high-temperature process being performed in the process chamber, such as a high-temperature cleaning process.

Each section 506₁-506₄ of the cooling channel 506 can include a central portion 1D that forms part of the central loop 525. The inlet 510 can be directly connected to the central portions 1D of the third section 506₃ and the fourth section 506₄ through the first segment 521.

With reference to the first section 506₁ and the fourth section 506₄, in each section 506₁-506₄ (1) a first turn 51 connects the first portion 1D to a more radially outward second portion 2D, (2) a second turn 52 connects the second portion 2D to a more radially outward third portion 3D which is split into a first segment 3D₁ and a second segment 3D₂, (3) a pair of third turns 53A, 53B connect the corresponding third segments 3D₁, 3D₂ to a pair of corresponding radially outward fourth portions 4D₁, 4D₂, (4) a pair of fourth turns 54A, 54B connect the corresponding fourth portions 4D₁, 4D₂ to a pair of corresponding radially outward fifth portions 5D₁, 5D₂, and (5) a pair of fifth turns 55A, 55B connect the corresponding fifth portions 5D₁, 5D₂ to a pair of corresponding radially outward sixth portions 6D₁, 6D₂ that join together at the outlet 511-514 for the corresponding section 506₁-506₄.

Each section 506₁-506₄ of the cooling channel 506 includes only radial outward turns. Using sections that only include radially outward turns can be used to assist in providing more cooling per unit area of the cooling channel 506 at more radial inward positions, which can be useful when center cooling of the reflector is significantly more of a concern than cooling the outer edge (e.g., edge 503) of the reflector.

In some embodiments two or more or three or more of the portions or segments can each extend past a same angular location in a given sector, such as a first angular location 591, but at a different radial distance relative to the center C. For example, each of the portions and segments 1D, 2D, 3D₁, 4D₁, 5D₁, and 6D₁ extend past the first angular location 591 in the sector but at a different radial distance relative to the center C. At the first angular location 591, each portion 2D-6D₁ is downstream relative to a next closest radially inward portion 1D-5D₁. At some angular locations in each section 506₁-506₄, more than half of the portions 1D-6D are downstream relative to a next closest radially inward portion 1D-6D. The first angular location 591 is shown in the fourth sector 505C₄, but a corresponding angle is also located in each of the other sectors 505C₁₋₃.

The embodiments of cooling channels provided in this disclosure are arranged to generally provide a coolant flow path that moves through the bottom plate in an entirely or primarily radial outward direction, which can be used to increase the cooling per unit area of cooling channel near the center of the bottom plate relative to the cooling per unit area of regions of the cooling channels further from the center of the bottom plate and closer to the outer edge of the bottom plate. These radially outward cooling flow paths can assist in maintaining the center of the bottom plate of the reflector below temperature thresholds that may damage the bottom plate when exceeded. Providing coolant through these radially outward cooling flow paths can enable higher temperature cleaning processes to be performed in the interior of the process chamber that includes these reflectors, which can enable process chambers to be cleaned to a higher level of cleanliness and/or allow cleaning processes to be performed more quickly.

For each of the embodiments and variations described above, the one or more inlets and outlets can be switched to reverse the cooling flow paths described above. For example, with reference to FIG. 2, the coolant can be provided into inlets 211, 212 (previously described as outlets) and flow through the cooling channel to a common outlet 210 (previously an inlet). Reversing these coolant flow paths can be useful for embodiments for increasing cooling of edge regions of the reflector compared to center regions of the reflector.

While the foregoing is directed to examples of the present disclosure, other and further examples of the disclosure may be devised without departing from the basic scope thereof, and the scope thereof is determined by the claims that follow.

What is claimed is:

1. A reflector for use in a semiconductor process chamber comprising:
a body; and
a bottom plate connected to a lower portion of the body, the bottom plate having a bottom surface, a top surface, and one or more side surfaces connecting the bottom surface with the top surface, wherein
a cross section of the bottom plate that extends to opposing locations on the one or more side surfaces includes a center,
the cross section is divided into two or more sectors that extend from the center of the cross section, and
the cross section includes a cooling channel comprising an inlet and one or more outlets.

2. The reflector of claim 1, wherein the cooling channel further comprises:
a plurality of sections, each section located in a sector of the two or more sectors of the cross section of the bottom plate, wherein
each section includes three or more portions spaced apart from each other at different radial distances from the center at a first angular location in the sector relative to the center, and
more than half of the three or more portions are downstream relative to a next closest radially inward portion of the three or more portions.

3. The reflector of claim 2, wherein
the cooling channel includes a central loop that is a first portion of the cooling channel downstream from the inlet to extend at least 30 degrees around the center of the cross section, and
the central loop is a most radially inward portion of the three or more portions at the first angular location.

4. The reflector of claim 3, wherein the central loop extends greater than 180 degrees around the center of the cross section.

5. The reflector of claim 2, wherein each of the three or more portions are downstream relative to the corresponding next closest radially inward portion of the three or more portions.

6. The reflector of claim 1, wherein at least one of the one or more outlets is located at a greatest radial distance from the center for the cooling channel.

7. The reflector of claim 2, wherein the two or more sectors includes four or more sectors.

8. The reflector of claim 2, wherein each section of the cooling channel includes three or more turns of 180 degrees in a radially outward direction.

9. The reflector of claim 2, wherein
each section includes three or more turns of 180 degrees, and
a number of the three or more turns in a radially outward direction from upstream to downstream is greater than a number of the three or more turns in a radially inward direction from upstream to downstream.

10. The reflector of claim 1, wherein the bottom surface of the bottom plate is formed of gold.

11. A process chamber comprising:
a chamber body disposed around a process volume;
a substrate support in the process volume; and
a reflector positioned over the substrate support, the reflector comprising:
a bottom plate having a bottom surface facing the substrate support, a top surface, and one or more side surfaces connecting the bottom surface with the top surface, wherein
a cross section of the bottom plate that extends to opposing locations on the one or more side surfaces includes a center,
the cross section is divided into two or more sectors that extend from the center of the cross section, and
the cross section includes a cooling channel comprising an inlet and one or more outlets.

12. The process chamber of claim 11, wherein the cooling channel further comprises a plurality of sections, each section located in a sector of the two or more sectors of the cross section of the bottom plate, wherein
each section includes three or more portions spaced apart from each other at different radial distances from the center at a first angular location relative to the center, and
more than half of the three or more portions are downstream relative to a next closest radially inward portion of the three or more portions.

13. The process chamber of claim 12, wherein
the cooling channel includes a central loop that is a first portion of the cooling channel downstream from the inlet to extend at least 30 degrees around the center of the cross section, and
the central loop is a most radially inward portion of the three or more portions at the first angular location.

14. The process chamber of claim 13, wherein the central loop extends greater than 180 degrees around the center of the cross section.

15. The process chamber of claim 12, wherein each of the three or more portions are downstream relative to the corresponding next closest radially inward portion of the three or more portions.

16. The process chamber of claim 11, wherein at least one of the one or more outlets is located at a greatest radial distance from the center for the cooling channel.

17. The process chamber of claim 12, wherein the two or more sectors includes four or more sectors.

18. The process chamber of claim 12, wherein each section includes three or more turns of 180 degrees in a radially outward direction.

19. The process chamber of claim 12, wherein
each section includes three or more turns of 180 degrees, and
a number of the three or more turns in a radially outward direction is greater than a number of the three or more turns in a radially inward direction.

20. A process chamber comprising:
a chamber body disposed around a process volume;
a substrate support in the process volume;
a reflector positioned over the substrate support, the reflector comprising:
a bottom plate having a bottom surface facing the substrate support, a top surface, and one or more side surfaces connecting the bottom surface with the top surface, wherein
a cross section of the bottom plate that extends to opposing locations on the one or more side surfaces includes a center,
the cross section is divided into four or more sectors that extend from the center of the cross section, and
the cross section includes a cooling channel comprising:
an inlet and one or more outlets; and
a plurality of sections, each section located entirely in a sector of the four or more sectors of the cross section of the bottom plate, wherein each section each section includes three or more turns of 180 degrees in a radially outward direction.
